(19) United States
(12) Patent Application Publication
(10) Pub. No.: US 2025/0259918 A1
(43) Pub. Date: Aug. 14, 2025

(54) ELECTRONIC MODULE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/046,513

(22) Filed: Feb. 6, 2025

(30) Foreign Application Priority Data
Feb. 14, 2024 (JP) 2024-020367

(51) Int. Cl. H01L 23/495; H01L 23/00; H01L 23/31; H01L 23/373; H01L 23/498

(52) U.S. Cl. CPC H01L 23/49562; H01L 23/49833; H01L 23/49844; H01L 24/02; H01L 24/06; H01L 24/08; H01L 23/3121; H01L 23/3735; H01L 23/49568; H01L 24/32; H01L 24/40; H01L 24/73; H01L 2224/0212; H01L 2224/0603; H01L 2224/06181; H01L 2224/08225; H01L 2224/32225; H01L 2224/40225; H01L 2224/73213; H01L 2224/73263; H01L 2924/13091; H01L 2924/3011

(57) ABSTRACT

An electronic module includes: a first board; a chip disposed on the first board and having a main electrode and a control electrode on a surface thereof on a side opposite to a surface thereof on a first board side; a power chip connection terminal disposed on the main electrode and being electrically connected to the main electrode; and a signal chip connection terminal having a columnar shape disposed on the control electrode and being electrically connected with the control electrode.

### CROSS REFERENCE TO RELATED APPLICATIONS

This application claims priority to Japanese Patent Application No. 2024-20367, filed on Feb. 14, 2024, which is expressly incorporated herein by reference in its entirety.

### TECHNICAL FIELD

The present invention relates to an electronic module.

### BACKGROUND ART

Conventionally, there has been known an electronic module that includes: a chip mounted on a board; and a power chip connection terminal mounted on a main electrode of the chip (see patent literature 1, for example).

As illustrated in FIG. 7, a conventional electronic module 900 includes: a first board 910; a chip 920 that is disposed on the first board 910 and has a main electrode 921 and a control electrode 922 on a surface thereof on a side opposite to a first board 910 side; and a power chip connection terminal 930 having a columnar shape that is disposed on the main electrode 921 and is electrically connected to the main electrode 921. In the conventional electronic module 900, the control electrode 922 is connected to a wiring 913 disposed on the first board 910 via a wire W.

In the conventional electronic module 900, a second board 970 is disposed at a position that opposedly faces the first board 910, and the chip 920 and the second board 970 are connected to each other via the power chip connection terminal 930. Further, the first board 910 and the second board 970 are connected to each other by an internal connection terminal 950.

### PRIOR ART LITERATURE

### Patent Literature

[Japanese Patent Literature 1] JP-A-2020-503697

### SUMMARY OF INVENTION

### Technical Problem

As described above with respect to the conventional electronic module 900, in the case where the second board 970 is disposed at the position that opposedly faces the first board 910, in a manufacturing process, it is necessary to perform a reflow in a state where the first board 910, the chip 920, the second board 970 and the like are pressed from both sides, that is, a first board 910 side and a second board 970 side.

However, in the case where the reflow is performed in a state where the first board 910 and the second board 970 are being pressed, as illustrated in FIG. 8, the main electrode 921 is physically pressed by the power chip connection terminal 930 and hence, the chip 920 is inclined whereby the chip 920 may not be held horizontally with respect to the first board 910 thus giving rise to a possibility that it is difficult to secure the reliability of the electronic module 900 sufficiently. In FIG. 8, a connection member 940 formed by applying working to a metal-made flat plate in place of the wire W, it is estimated that the same possibility arises.

With respect to this drawback, besides the case where the reflow is performed in a state where the first board 910 and the second board 970 are pressed, also in a case where the board is disposed on only one surface, the main electrode 921 is physically pressed by its own weight of the power chip connection terminal 930 or the like so that the chip 920 is inclined. Also in this case, there is a possibility that the chip 920 cannot be horizontally held with respect to the first board 910.

The present invention has been made in view of the above-mentioned circumstances, and it is an object of the present invention to provide an electronic module that can sufficiently secure its reliability.

### Solution to Problem

An electronic module according to the present invention includes: a first board; a chip disposed on the first board and having a main electrode and a control electrode on a surface thereof on a side opposite to a surface thereof on a first board side; a power chip connection terminal disposed on the main electrode and being electrically connected to main electrode; and a signal chip connection terminal having a columnar shape disposed on the control electrode and being electrically connected with the control electrode.

### Advantageous Effects of the Present Invention

According to the electronic module of the present invention, the electronic module includes the signal chip connection terminal having a columnar shape that is disposed on the control electrode and is electrically connected with the control electrode and hence, even in a case where the main electrode is physically pressed by the power chip connection terminal, it is possible to prevent the occurrence of a phenomenon that the chip is inclined by pressing the control electrode using the signal chip connection terminal. Accordingly, the chip can be held horizontally with respect to the first board. As a result, the electronic module can secure sufficient reliability.

In a case where a connection member is formed by bending a small part (see symbol 940 in FIG. 8, for example), it is difficult to increase bending accuracy and hence, it is difficult to perform positioning of the connection member with respect to a small connection region such as a gate electrode with high accuracy. However, according to the electronic module of the present invention, the electronic module includes the signal chip connection terminal having a columnar shape and hence, it is unnecessary to bend a small part whereby the connection terminal can be positioned with respect to a small connection region such as the gate electrode.

### BRIEF DESCRIPTION OF DRAWINGS

FIG. 1 is perspective view of an electronic module 1 according to an embodiment 1.

FIG. 2 is a view illustrating an internal structure of the electronic module 1 according to the embodiment 1. FIG. 2 is a view where the illustration of a mold resin 80 is omitted from the perspective view in FIG. 1.

FIG. 3A and FIG. 3B are views illustrating an internal structure of the electronic module 1 according to the embodiment 1. FIG. 3A is a plan view where the illustration of the configuration on a second board 70 side and the mold resin 80 is omitted from FIG. 1, and FIG. 3B is a plan view where the illustration of a first support member 60 and a second support member 62 is omitted from FIG. 3A.

FIG. 4A and FIG. 4B are views illustrating a power chip connection terminal 30 and a signal chip connection terminal 40 in the embodiment 1. FIG. 4A is a perspective view illustrating the power chip connection terminal 30 and the signal chip connection terminal 40, and FIG. 4B is a schematic side view illustrating the power chip connection terminal 30 and the signal chip connection terminal 40. Arrows in FIG. 4B indicate forces (pressures) applied to a chip 20. The same goes for the configuration illustrated in FIG. 5B and FIG. 6B. Further, for the sake of brevity of the description, the illustration of conductive bonding materials other than a conductive bonding material S1 between the first board 10 and the chip 20 is omitted. The same goes for the configuration illustrated in FIG. 5B and FIG. 6B.

FIG. 5A and FIG. 5B are views illustrating a power chip connection terminal 30a and a signal chip connection terminal 40 in an embodiment 2. FIG. 5A is a plan view illustrating the power chip connection terminal 30a and a gate electrode 22, and FIG. 5B is a schematic side view illustrating the power chip connection terminal 30a and the signal chip connection terminal 40.

FIG. 6A and FIG. 6B are views illustrating a power chip connection terminal 30b and the signal chip connection terminal 40 in an embodiment 3. FIG. 6A is a plan view illustrating the power chip connection terminal 30b and the gate electrode 22, and FIG. 6B is a schematic side view illustrating the power chip connection terminal 30b and the signal chip connection terminal 40.

FIG. 7 is a side view illustrating a conventional electronic module 900. In FIG. 7, symbols 912, 914 indicate wirings and symbol S1 indicates solder.

FIG. 8 is a schematic essential portion enlarged side view illustrating a drawback of the conventional electronic module 900. Symbol S3 indicates a solder, and symbol 935 indicates a spacer. Further, an arrow in the vicinity of a power chip connection terminal 930 in FIG. 8 indicates a force (pressure) applied to the chip 920, and an arrow in the vicinity of a connection member 940 indicates a direction of a force that lifts a control electrode 922 side of the chip 920.

### DESCRIPTION OF EMBODIMENTS

Hereinafter, electronic modules according to the present invention are described based on embodiments illustrated in the drawings. The embodiments described hereinafter are not intended to limit the present invention called for in claims. Further, it is not always the case that all of various elements described in the embodiments and combinations of these elements are indispensable as means to solve the problem of the present invention.

### Embodiment 1

### 1. Configuration of Electronic Module 1 According Embodiment 1

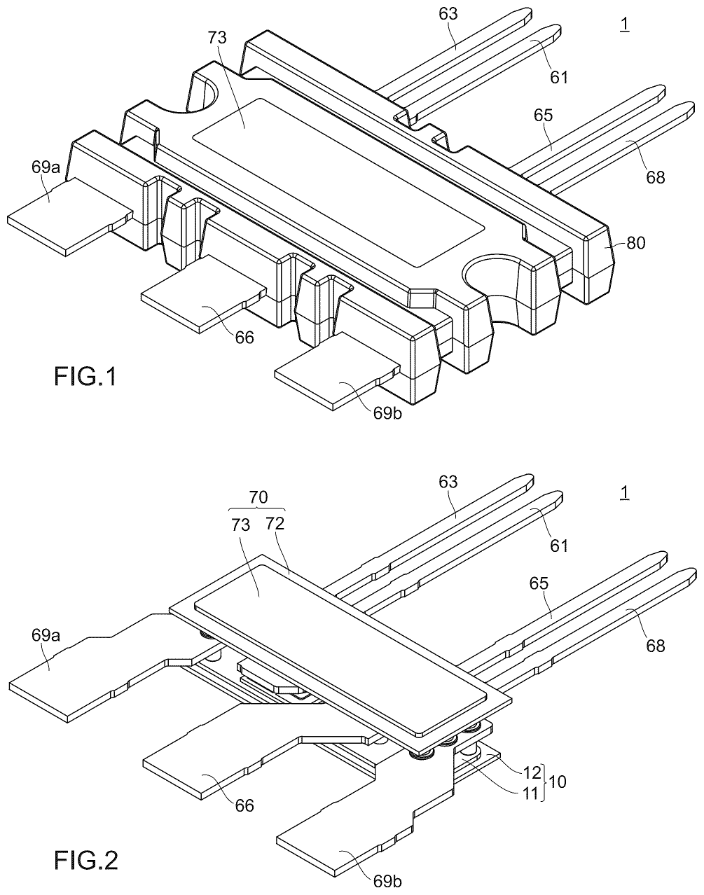

As illustrated in FIG. 1, the electronic module 1 according to the embodiment 1 is an electronic module molded by a mold resin 80. A metal plate for heat radiation is disposed on upper surface and a lower surface of the electronic module 1 (the metal plate on the upper surface of the electronic module 1 being indicated by 73 and the lower surface of the electronic module 1 being not illustrated). Power terminals 69a, 66, 69b that constitute external terminals through which a main current flows extend from one side surface of the electronic module 1, and signal terminals 63, 68 and sensor terminals 61, 65 that constitute external terminals extend from the other side surface of the electronic module 1.

As illustrated in FIG. 1 to FIG. 4B, the electronic module 1 includes: a first board 10, a chip 20; power chip connection terminals 30, 31; a spacer 35; signal chip connection terminals 40, 41; internal connection terminals 50, 51; first support members 60, 64; second support members 62, 67; external terminals (power terminals 69a, 66, 69b, signal terminals 63, 68 and SENSE terminals 61, 65), a second board 70 (see FIG. 2); and the mold resin 80 (see FIG. 1).

The first board 10 is a direct copper bonding board (DCB board) that includes: an insulation board (ceramic board) 12; a circuit wiring 11 formed on one surface (upper surface) of the insulation board 12; and a metal plate for heat radiation (not illustrated in the drawing) formed on the other surface (lower surface) of the insulation board 12.

The second board 70 is also a DCB board that includes: an insulation board (ceramic board) 72; a circuit wiring (not illustrated in the drawing) formed on one surface (lower surface in FIG. 2) of the insulation board 12; and a metal plate 73 for heat radiation formed on the other surface (upper surface in the drawing) of the insulation board 72. The first board 10 and the second board may be formed of a suitable board such as a printed circuit board.

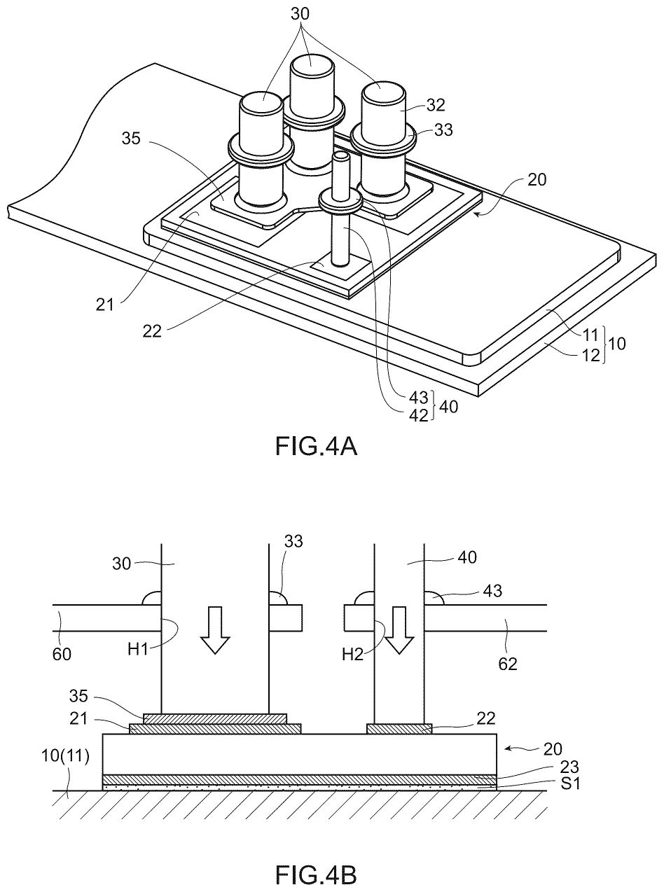

The chip 20 is disposed on the circuit wiring 11 of the first board 10 and is formed of a metal-oxide-semiconductor field-effect transistor (MOSFET) of a vertical type where a source electrode 21 (main electrode) and a gate electrode 22 (control electrode) are disposed on a surface of the chip 20 on a side opposite to a surface of a first board 10 side, and a drain electrode 23 (see FIG. 4B) is formed on the surface on the first board 10 side. The source electrode 21 is divided in three, and occupies three regions in a case where the rectangular chip 20 as viewed in a plan view is divided in four. In the chip 20 divided in four as viewed in a plan view, the gate electrode 22 is formed at a corner portion that is an outer edge of a region where the source electrode 21 is not formed. The drain electrode 23 is formed on the entire surface of the chip 20 on the first board 10 side.

To secure a large area of the main electrode, the source electrode 21 occupies a considerable portion of a surface of the chip 20. On the other hand, to prevent short circuiting between the source electrode 21 and the control electrode (gate electrode 22), it is necessary to dispose the source electrode 21 spaced apart from a control electrode (gate electrode 22) by a predetermined distance. As a result, a possibility that the power chip connection terminal 30 is connected at a position away from the center of gravity of the chip 20 is increased and hence, the chip 20 is liable to be inclined. The signal chip connection terminal 40 described later is particularly effective also with respect to such a case.

The spacer 35 is a plate-shaped member formed straddling over the three divided source electrode 21. Recesses that receive power chip connection terminals 30 described later are formed on the spacer 35, and the spacer 35 is bonded to the power chip connection terminals 30 in the recesses via a conductive bonding material (for example, solder).

The power chip connection terminal 30 is a columnar member made of a conductive material (for example, a metal material). The power chip connection terminal 30 is disposed on the source electrode 21 (main electrode). One end (lower side end portion) of the power chip connection terminal 30 is electrically connected with the source electrode 21 (main electrode), and the other end (upper side end portion) is electrically connected to a wiring (not illustrated in the drawing) of the second board 70. A lower side end portion of the power chip connection terminal 30 is bonded to the recess of the spacer 35 via a conductive bonding material (for example, solder), and upper side end portion of the power chip connection terminal 30 is bonded to a wiring of the second board 70 via a conductive bonding material (for example, solder).

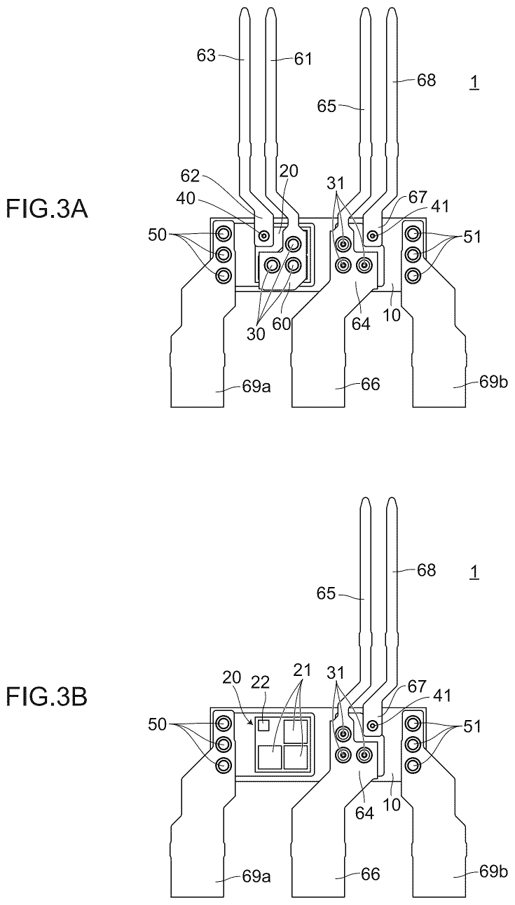

As illustrated in FIG. 3A, the power chip connection terminal 30 is supported by the first supporting member 60 in a state where the power chip connection terminal 30 passes through a first through hole H1 (see FIG. 4B) formed in the first support member 60 described later. The power chip connection terminal 30 is press-fitted into the first through hole H1.

As illustrated in FIG. 4A, the power chip connection terminal 30 has a body portion 32 having a circular columnar shape and a flange portion 33 having a ring shape formed at an intermediate position of the body portion 32 in a height direction. A lower surface of the flange portion 33 is bonded to the first support member 60. The shape of the body portion 32 is not limited to a circular columnar shape, and may be a rectangular columnar shape, or may adopt as suitable columnar shapes.

The signal chip connection terminal 40 is a columnar member made of a conductive material (for example, a metal material). The signal chip connection terminal 40 is mounted on the gate electrode 22 (control electrode). One end (lower side end portion) of the signal chip connection terminal 40 is electrically connected with the gate electrode 22 (control electrode), and the other end (upper side end portion) of the signal chip connection terminal 40 is electrically connected to a wiring disposed on the second board 70 (not illustrated in the drawing). The lower side end portion of the signal chip connection terminal 40 is bonded to the gate electrode 22 (control electrode) via a conductive bonding material (for example, solder), and the upper side end portion of the signal chip connection terminal 40 is connected to the wiring disposed on the second board 70 via a conductive bonding material (for example, solder). The signal chip connection terminal 40 may not be bonded to the second board 70.

As illustrated in FIG. 3A, the signal chip connection terminal 40 is supported by a second support member 62 in a state where the signal chip connection terminal 40 passes through a second through hole H2 (see FIG. 4B) formed in the second support member 62 described later. The signal chip connection terminal 40 is inserted into the second through hole H2.

As illustrated in FIG. 4A, the signal chip connection terminal 40 has a body portion 42 having a circular columnar shape and a flange portion 43 having a ring shape formed at an intermediate position of the body portion 42 in a height direction. A lower surface of the flange portion 43 is bonded to the second support member 62. The shape of the body portion 42 is not limited to a circular columnar shape, and may be a rectangular columnar shape, or may adopt other suitable columnar shapes. The signal chip connection terminal 40 may not have the flange portion 43.

A chip (not illustrated in the drawing) is disposed on a circuit wiring (not illustrated in the drawing) of the second board 70. A spacer (not illustrated in the drawing) and the power chip connection terminal 31 are disposed over the source electrode (a side where the chip is disposed with respect to the second board 70 being set as an upper side) of the chip (not illustrated in the drawing), and the signal chip connection terminal 41 is disposed over the gate electrode. These configurations are the same configurations with the configurations obtained by arranging the chip 20, the spacer 35, the power chip connection terminal 30 and the signal chip connection terminal 40 on the first board 10 upside down. Accordingly, the description of these configurations is omitted.

Further, as illustrated in FIG. 3A and FIG. 3B, the first support member 64 is disposed at the intermediate position of the power chip connection terminal 31 in the height direction, and the power chip connection terminal 31 is supported by the first support member 64. Further, the second support member 67 is disposed at the intermediate position of the signal chip connection terminal 41 in the height direction, and the signal chip connection terminal 41 is supported by the first support member 64.

The internal connection terminals 50, 51 are columnar members that connect to the first board 10 and the second board 70 to each other. In the embodiment 1, three internal connection terminals 50, 51 are disposed at an end portion of the first board 10. At an intermediate position of the internal connection terminal 50 in a height direction, the power terminal 69a that constitutes an external terminal is connected, and the power terminal 69b that constitutes an external terminal is connected at an intermediate position of the internal connection terminal 51 in a height direction.

The first support member 60 is a conductive plate-shaped member having three first through holes H1. The power chip connection terminal 30 is inserted (press-fitted) to each first through hole H1. The first support member 60 extends in a horizontal direction toward the outside the mold resin 80 (see FIG. 1). A portion of the first support member 60 outside the mold resin 80 forms the SENSE terminal 61 that constitutes an external terminal.

The first support member 64 is a conductive plate-shape member that has three first through holes. The first support member 64 extends horizontally outside the mold resin 80 (see FIG. 1) in a direction opposite to a direction that the SENSE terminal 61 extends, and a portion of the first support member 64 outside the mold resin 80 constitutes an external terminal. An external terminal that extends in the same direction as the SENSE terminal 61 is a SENSE terminal 65 that is connected to a source electrode of a chip (not illustrated in the drawing) disposed on the second board 70, and an external terminal that extends in the direction opposite to the SENSE terminal 61 is a power terminal 66.

The second support member 62 is a conductive plate-shaped member having one second through hole H2. The second support member 62 extends horizontally outside the mold resin 80 (see FIG. 1), and a portion of the second support member 62 outside the mold resin 80 constitutes an external terminal (signal terminal 63).

The second support member 67 is a plate-shaped member having one second through hole (not illustrated in the drawing). The second support member 67 extends horizontally outside the mold resin 80 (see FIG. 1), and a portion of the second support member 67 outside the mold resin 80 constitutes an external terminal (signal terminal 68).

The first support members 60, 64, the second support members 62, 67, the external terminals (signal terminals 63, 68, SENSE terminals 61, 65, power terminals 66, 69a, 69b) may be formed of one lead frame.

The mold resin 80 (see FIG. 1) seals the first board 10, the chip 20, the first support member 60, the second support member 62, the power chip connection terminal 30 and the signal chip connection terminal 40. The mold resin 80 is made of a thermosetting molding material obtained by adding a silica filler and the like to the epoxy resin that is a main component. The mold resin 80 protects the chip 20 and the like from heat, light, moisture and the like.

### 2. Advantageous Effects Acquired by Embodiment 1

The electronic module 1 according to the embodiment 1 includes the signal chip connection terminal 40 that is disposed on the control electrode (gate electrode 22) and is electrically connected with the control electrode (gate electrode 22). With such a configuration, even in a case where the main electrode (source electrode 21) is physically pressed by the power chip connection terminal 30, it is possible to prevent the occurrence of the phenomenon that the chip 20 is inclined by pressing the control electrode (gate electrode 22) using the signal chip connection terminal 40. Accordingly, the chip 20 can be held horizontally with respect to the first board 10. As a result, the electronic module 1 can secure sufficient reliability.

In a case where the conventional connection member is formed by bending a small part (see symbol 940 in FIG. 8, for example), it is difficult to increase bending accuracy and hence, it is difficult to perform positioning of the connection member with respect to a connection region such as the control electrode having a small connection area with high accuracy. However, according to the electronic module 1 of the embodiment 1, the electronic module 1 includes the signal chip connection terminal 40 having a columnar shape and hence, it is unnecessary to bend a small part whereby the connection terminal can be positioned with respect to a small connection region such as the gate electrode 22 with high accuracy.

The electronic module 1 of the embodiment 1 includes the plate-shaped first support member 60 having the first through hole H1 and the second support member 62 having the second through hole H2, the power chip connection terminal 30 is supported by the first support member 60 in a state where the power chip connection terminal 30 passes through the first through hole H1, the signal chip connection terminal 40 is supported by the second support member 62 in a state where the signal chip connection terminal 40 passes through the second through hole H2 and hence, the power chip connection terminal 30 and the signal chip connection terminal 40 can be stably supported in a state where the power chip terminal 30 and the signal chip connection terminal 40 stand upright. Further, a circuit wiring can be constituted by the first support member 60, the second support member 62, the power chip connection terminal 30 and the signal chip connection terminal 40 and hence, a mounting area for wiring on the first board 10 and the second board 70 can be made small whereby downsizing of the electronic module can be realized. Further, the wiring can be constituted in a stereoscopic space and hence, it is possible to provide the module having high degree of freedom in designing the module. Still further, by uniformly pressing the chip 20, the chip 20 can be held horizontally with respect to the first board 10 with more certainty and hence, it is possible to provide the module that secures more reliability.

According to the electronic module 1 of the embodiment 1, the second support members 62, 67 extend in a horizontal direction to the outside the mold resin 80, and portions of the second support members 62, 67 outside the mold resin 80 constitute the signal terminals 63, 68 of the gate electrode 22. Accordingly, a circuit that connects the gate electrode 22 of the chip 20 and the signal terminals 63, 68 can be constituted of the signal chip connection terminals 40, 41 and the second support members 62, 67. Accordingly, mounting areas for wiring on the first board 10 and the second board 70 can be made small and hence, downsizing of the electronic module is further enhanced and, at the same time, it is possible to provide the electronic module having the further higher degree of freedom in designing the electronic module.

According to the electronic module 1 of the embodiment 1, the first support members 60, 64 extend in a horizontal direction to the outside the mold resin 80, and portions disposed outside the mold resin 80 constitute the external terminals (SENSE terminals 61, 65 and the power terminal 66) and hence, a circuit that connects the source electrode 21 of the chip 20 and the external terminals to each other can be constituted by the power chip connection terminals 30, 31 and the first support members 60, 64. Accordingly, also from this point of view, mounting areas for wiring on the first board 10 and the second board 70 can be made small and hence, downsizing of the electronic module is further enhanced.

According to the electronic module 1 of the embodiment 1, the second board 70 is disposed at a position that opposedly faces the first board 10, and the power chip connection terminal 30 and the signal chip connection terminal 40 are connected to the second board 70. Accordingly, heat can be radiated from both surfaces of the first board 10 and the second board 70 thus providing the electronic module having high heat radiation property. Further, the first board 10, the chip 20, the second board 70 and a chip (being disposed on the second board) can be connected to each other by the power chip connection terminal 30 and the signal chip connection terminal 40 and hence, the shape stability of the electronic module 1 can be enhanced.

According to the electronic module 1 of the embodiment 1, the main electrode (source electrode 21) is divided into a plurality of (three) electrode portions, and the power chip connection terminals 30, 31 are disposed corresponding to three respectively divided electrode portions and hence, the supply of electricity between the power chip connection terminals 30. 31 and three divided electrode portions is facilitated. A bias of a current density minimally occurs and hence, heat generated from the chip 20 can be radiated (transferred) to the second board 70 via the power chip connection terminals 30, 31.

In the electronic module 1 of the embodiment 1, the gate electrode 22 is disposed on an outer edge portion of the chip 20. With such a configuration, the gate electrode 22 can be connected with the outside easily and, at the same time, the source electrode 21 can secure a large area.

According to the electronic module 1 of the embodiment 1, the spacer 35 is disposed between the main electrode (source electrode 21) and the power chip connection terminal 30 and hence, a thermal stress applied to a conductive bonding material between the main electrode (source electrode 21) and the power chip connection terminal 30 can be alleviated.

### Embodiment 2

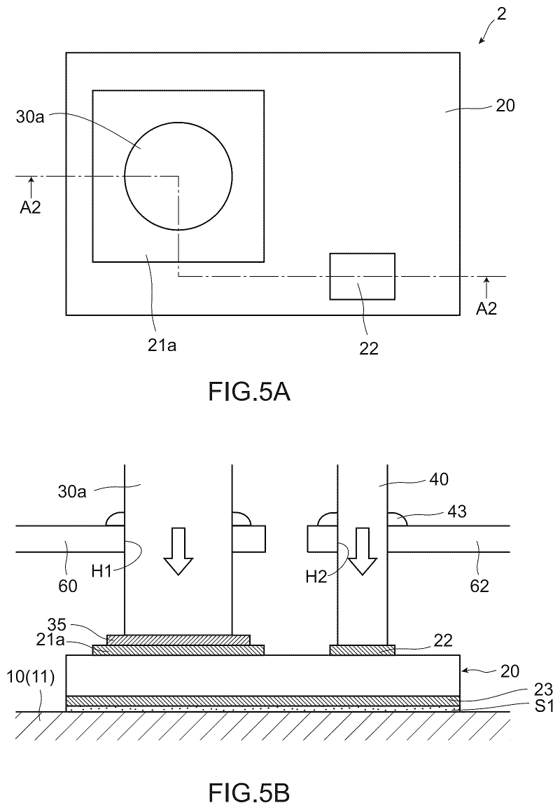

An electronic module 2 according to the embodiment 2 has basically substantially the same configuration as the electronic module 1 according to the embodiment 1. However, the electronic module 2 according to the embodiment 2 differs from the electronic module 1 according to the embodiment 1 with respect to the configuration of a source electrode and the configuration of a power chip connection terminal. That is, in the electronic module 2 according to the embodiment 2, as illustrated in FIG. 5A and FIG. 5B, a source electrode is not divided in three and one source electrode 21a having a relatively large area is formed, and one power chip connection terminal 30a that corresponds to the source electrode 21a is disposed.

In this manner, the electronic module 2 according to the embodiment 2 differs from the case of the electronic module 1 according to the embodiment 1 with respect to the configuration of the source electrode and the configuration of the power chip connection terminal. However, in the same manner as the electronic module 1 according to the embodiment 1, the electronic module 2 includes a signal chip connection terminal 40 that is disposed on the gate electrode 22, and is electrically connected to the gate electrode 22. Accordingly, the electronic module 2 can secure sufficient reliability and, at the same time, the signal chip connection terminal 40 can be positioned with high accuracy also with respect to a small connection region such as the gate electrode 22.

The semiconductor module 2 according to the embodiment 2 has basically substantially the same configuration as the semiconductor module 1 according to the embodiment 1 with respect to the points other than the configuration of the source electrode and the configuration of the power chip connection terminal. Accordingly, the semiconductor module 2 according to the embodiment 2 can acquire advantageous effects corresponding to the advantageous effects of the semiconductor module 1 according to the embodiment 1 amongst all the advantageous effects that the embodiment 1 acquires.

### Embodiment 3

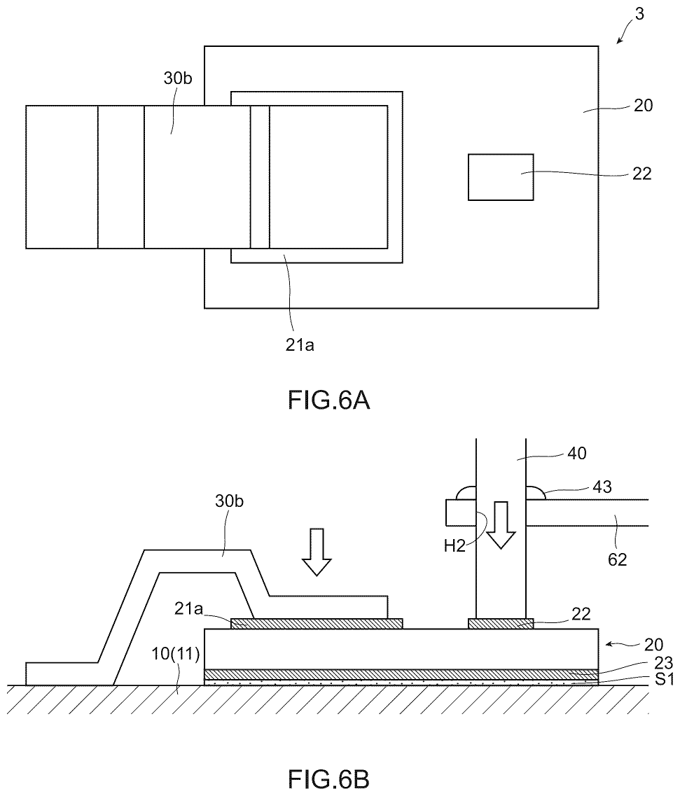

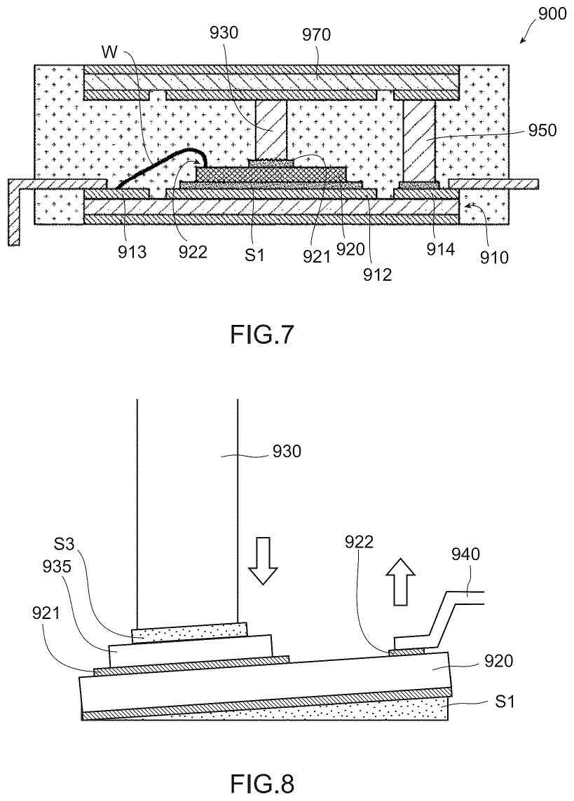

An electronic module 3 according to the embodiment 3 has basically substantially the same configuration as the electronic module 1 according to the embodiment 1. However, the electronic module 3 according to the embodiment 3 differs from the electronic module 2 according to the embodiment 2 with respect to the configuration of a power chip connection terminal. That is, in the electronic module 3 according to the embodiment 3, as illustrated in FIG. 6A and FIG. 6B, the power chip connection terminal 30b is not a terminal having a columnar shape, but is formed in a shape such that the power chip connection terminal 30b spans or is bridged between two electrode portions (so-called a clip shape or a connector shape) as a bridge (so-called clip shape or connector shape).

In the embodiment 3, the power chip connection terminal 30b is not a terminal having a columnar shape. A chip 20 is pressed when the power chip connection terminal 30b is placed on a source electrode 21a of the chip 20, or the chip 20 is pressed due to its own weight of the power chip connection terminal 30b. Also in this case, floating of the chip can be prevented by providing a signal chip connection terminal.

In the embodiment 3, the power chip connection terminal 30b is not a terminal having a columnar shape and hence, a member that corresponds to a first support member does not exist.

In this manner, although the electronic module 3 according to the embodiment 3 differs from the electronic module 2 according to the embodiment 2 with respect to the configuration of the power chip connection terminal, in the same manner as the electronic module 2 according to the embodiment 2, the electronic module 3 includes the signal chip connection terminal 40 that is disposed on the gate electrode 22, and is electrically connected with the gate electrode 22. Accordingly, the electronic module 3 can secure reliability sufficiently and, at the same time, the power chip connection terminal can be positioned with high accuracy even with respect to a small connection region such as a gate electrode 22.

The semiconductor module 3 according to the embodiment 3 has basically substantially the same configuration as the semiconductor module 2 according to the embodiment 2 with respect to the points other than the power chip connection terminal. Accordingly, the semiconductor module 3 according to the embodiment 3 can acquire advantageous effects corresponding to the advantageous effects of the semiconductor module 2 according to the embodiment 2 amongst all the advantageous effects that the embodiment 2 acquires.

The present invention has been described based on the above-mentioned embodiments heretofore, the present invention is not limited to the above-mentioned embodiments. The present invention can be carried out in various modes without departing from the gist of the present invention, and the following modifications are conceivable.
(1) The positions, the connections, the numbers and the like of the constitutional elements described in the above-mentioned respective embodiments (also including the respective modifications, the same understanding being applicable to the following description) are provided for an exemplifying purpose, and these values can be suitably changed so long as the technical feature of the present invention are not impaired.
(2) In the above-mentioned respective embodiments, a vertical type MOSFET is used as a chip. However, the present invention is not limited to such a MOSFET. A horizontal type MOSFET, that is, a horizontal MOSFET where a drain electrode is formed on a side opposite to a board side may be used. In this case, the MOSFET may be connected to both the source electrode and the drain electrode using power chip connection terminals, or the MOSFET may be connected to only either the source electrode or the drain electrode using the power chip connection terminal. Further, the chip is not limited to the MOSFET, and a transistor other than the MOSFET such as an IGBT, a thyristor or a triac may be also used as the chip. That is, so long as the chip includes the control electrode and the main electrode, any suitable element may be used.
(3) In the above-mentioned respective embodiments, the signal chip connection terminal is supported using the second support member. However, the present invention is not limited to such a configuration. The signal chip connection terminal may be supported without using the second support member.
(4) In the above-mentioned embodiment, the case is described where the present invention is applied to the electronic module that includes two chips. However, the present invention is not limited to such a configuration. The present invention may be applied to an electronic module that includes one chip, or the present invention may be applied to an electronic module that includes three or more chips.
(5) In the above-mentioned embodiments, a thickness of the first support members 60, 64 is set equal to a thickness of the second support members 62, 67. However, the present invention is not limited to such a configuration. The thickness of the first support members 60, 64, may be larger than the thickness of the second support members 62, 67. With such a configuration, the first support members 60, 64 connected to the source electrode allow a relatively large current to flow therethrough and, at the same time, can secure a sufficient width for supporting the power chip connection terminals 30, 31 having a relatively large cross-sectional area. Further, a diameter of the through hole can be increased and hence, it is possible to allow the power chip connection terminal 30, 31 having a relatively large cross-sectional area to pass through the through hole.

The signal chip connection terminals 40, 41 are formed of a pin terminal having a relatively small cross-sectional area through which a small amount of current flows. To allow such a signal chip connection terminal 40, 41 to pass through, it is necessary to make a diameter of the second through hole H2 small. However, in a case where a thickness of the second support member is large, it is not easy to form such a through hole having a small diameter. Accordingly, by setting a thickness of the second support members 62, 67 smaller than a thickness of the first support member 60, 64, the second through hole H2 having a small diameter can be formed.
(6) In the above-mentioned embodiment, a gap between the signal chip connection terminal 40, 41 and the second through hole H2 may be set larger than a gap between the power chip connection terminal 30, 31 and the first through hole H1. With such a configuration, in a manufacturing process, the signal chip connection terminal 40, 41 itself can be positioned at a proper position (enabling self alignment).

1. An electronic module comprising: a first board;
a chip disposed on the first board and having a main electrode and a control electrode on a surface thereof on a side opposite to a surface thereof on a first board side;
a power chip connection terminal disposed on the main electrode and being electrically connected to main electrode; and
a signal chip connection terminal having a columnar shape disposed on the control electrode and being electrically connected with the control electrode.

2. The electronic module according to claim 1, further comprising:
a first support member having a plate shape that includes a first through hole: and
a second support member having a plate shape that includes a second though hole, wherein
the power chip connection terminal is supported by the first support member in a state where the power chip connection terminal passes through the first though hole, and
the signal chip connection terminal is supported by the second support member in a state where the signal chip connection terminal passes through the second through hole.

3. The electronic module according to claim 2, wherein,
the first board, the chip, the first support member, the second support member, the power chip connection terminal and the signal chip connection terminal are sealed by a mold resin, and
the second support member extends to an outside the mold resin, and a portion of the second support member disposed outside the mold resin constitutes an external terminal of the control electrode.

4. The electronic module according to claim 2, wherein
the first board, the chip, the first support member, the second support member, the power chip connection terminal and the signal chip connection terminal are sealed by a mold resin, and
the first support member extends to an outside the mold resin, and a portion of the first support member disposed outside the mold resin constitutes an external terminal connected to the main electrode.

5. The electronic module according to claim 1, further comprising a second board disposed at a position that opposedly faces the first board, and the power chip connection terminal and the signal chip connection terminal are connected to the second board respectively.

6. The electronic module according to claim 2, wherein a thickness of the first support member is set larger than a thickness of the second support member.

7. The electronic module according to claim 2, wherein a gap formed between the signal chip connection terminal and the second through hole is larger than a gap formed between the power chip connection terminal and the first through hole.

8. The electronic module according to claim 1, wherein the main electrode is divided into a plurality of electrode portions, and the power chip connection terminal is disposed corresponding to the respective divided electrode portions.

9. The electronic module according to claim 1, wherein the control electrode is disposed on an outer peripheral portion of the chip.

10. The electronic module according to claim 1, wherein a spacer is disposed between the main electrode and the power chip connection terminal.
